(19) United States
(12) Patent Application Publication
(10) Pub. No.: US 2006/0249863 A1
(43) Pub. Date: Nov. 9, 2006

(54) Prism manufacturing method

(76) Inventor: Ping Chuang, Taoyuan Hsien (TW)

Correspondence Address: LOWE HAUPTMAN BERNER, LLP, 1700 DIAGONAL ROAD, SUITE 300, ALEXANDRIA, VA, 22314, US

(21) Appl. No.: 11/174,648

(22) Filed: Jul. 6, 2005

(30) Foreign Application Priority Data
May 9, 2005 (TW) 94114948

(51) Int. Cl. B29D 11/00; G02B 5/30; H01L 21/311

(52) U.S. Cl. 264/1.31; 264/2.5; 438/694

(57) ABSTRACT

The present invention describes a prism manufacturing method. According to the method, a semiconductor process method is applied to a wafer for forming a master mold. Then, an electroform process is applied to the master mold for forming a mold. The mold can be used to mass-produce prisms by a well-known manufacturing method.

### RELATED APPLICATIONS

The present application is based on, and claims priority from, Taiwan Application Serial Number 94114948, filed May 9, 2005, the disclosure of which is hereby incorporated by reference herein in its entirety.

### FIELD OF THE INVENTION

The present invention is about a prism manufacturing method, and more particularly is about using a semiconductor process technology to manufacture a prism.

### BACKGROUND OF THE INVENTION

A prism structure is often used in an optical element for changing a light route or splitting light. Typically, there are two methods to finish a prism structure. The first method is to use a machining method to form directly a prism. The second method is to use a machining method to form a mold. Then, the mold can be used to mass produce prisms by a well-known manufacturing method, such as compression mold or injection mold.

However, the first method is not suitable for mass production and may not produce a prism with nanometer-scale structure. Although the second method may resolve the mass production problem, the method requires very expensive equipment, such as an electron beam writer, an ion beam writer or a discharge process equipment, to form a nanometer-scale mold. In other words, the second method is expensive when the mold has a large area.

On the other hand, more and more optical elements are installed in an electrical apparatus. In other words, the optical elements have to be changed quickly to keep pace with changes in the electrical apparatus. Therefore, quick and cheap mold formation is extremely desirable.

### SUMMARY OF THE INVENTION

Therefore, it is the main purpose of the present invention to provide a prism manufacturing method.

Another purpose of the present invention is to provide a method of using a semiconductor process to form a prism structure.

A further purpose of the present invention is to provide a method for forming a prism mold.

Yet another purpose of the present invention is to provide a method for forming an optical element mold.

Accordingly, the present invention provides a prism manufacturing method that comprises the following steps. First, a semiconductor process method is applied on a wafer for forming a master mold. Then, an electroform process is applied to the master mold for forming a mold. Then, the mold can be used to mass produce prisms by a well-known manufacturing method, such as compression or injection molding.

According to one embodiment of the present invention, a method comprising the following steps is provided. First, a wet etching process is used to etch a silicon wafer to form different scale pyramid structures over the wafer. Next, a conductive layer is formed over the wafer. Then, an electroform process is applied to the wafer to form a mold. Finally, the mold can be used to mass produce prisms by a well-known manufacturing method, such as compression or injection molding.

According to another embodiment of the present invention, a method comprising the following steps is provided. First, after a oxide layer formed over a silicon wafer is patterned, a wet etching process is performed to form grooves on the surface of the wafer. Next, a conductive layer is formed over the grooves. Then, an electroform process is applied to the silicon wafer to form a mold. Finally, the mold can be used to mass produce prisms by a well-known manufacturing method, such as compression or injection molding.

### BRIEF DESCRIPTION OF THE DRAWINGS

The foregoing aspects and many of the attendant advantages of this invention will become more readily appreciated and better understood by referencing the following detailed description, when taken in conjunction with the accompanying drawings, wherein:

FIG. 1A to FIG. 1C illustrate the first embodiment of the present invention to form a mold with different scale pyramid structure;

FIG. 2A to FIG. 2F illustrate the second embodiment of the present invention to form a mold with strip structure; and

FIG. 3A to FIG. 3E illustrate the third embodiment of the present invention to form a mold with with same-scale pyramid structure.

### DETAILED DESCRIPTION OF THE PREFERRED EMBODIMENT

In the present invention, a semiconductor process is first applied on a wafer to form a prism structure in the wafer. Next, a modeling process is performed to form a mold with a structure corresponding to that of the prism structure formed in the wafer. Then, mass production of the prism can be realized by using this mold. Since no mechanical process or electrical beam process is involved in manufacturing the mold, the manufacturing cost is reduced. Moreover, a nanometer-scale prism structure can be formed by using semiconductor process. There are three embodiments described to interpret the present inveniton. However, the application of present invention does is not limited by the following three embodiments. Moreover, various semiconductor processes can be combined together to form required prism structures.

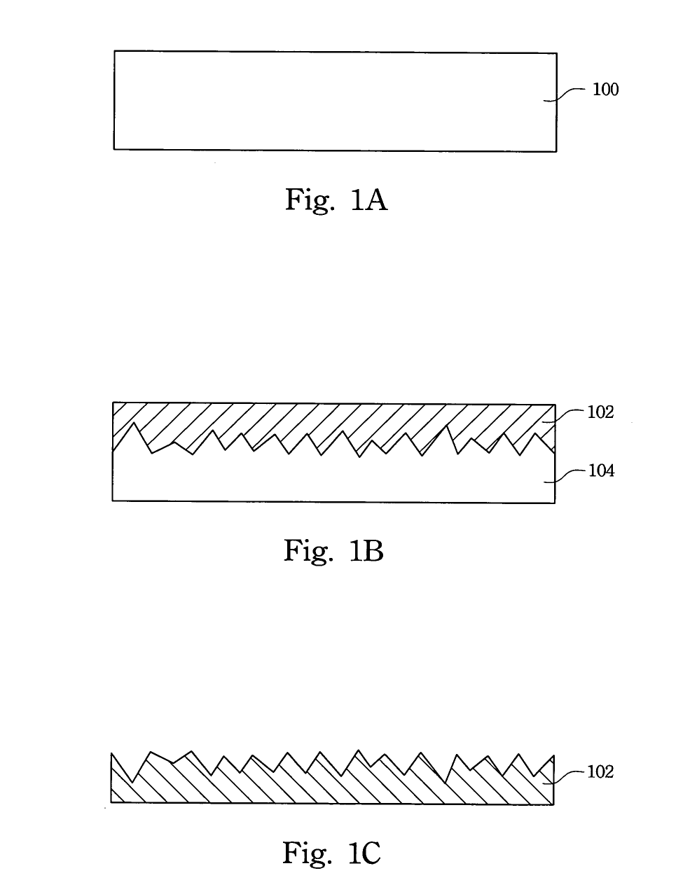

FIG. 1A to FIG. 1C illustrate the first embodiment, in which a mold with different scale pyramid structures is formed. First, as shown in the FIG. 1A, a silicon wafer 100 is provided. The silicon wafer 100 may be an N⁺-type or P⁺-type silicon wafer. According to the preferred embodiment, a silicon wafer with a Miller index <100> is used in the present invention to form the master mold 104 as shown in FIG. 1B.

The manufacturing method of manufacturing the master mold 104 illustrated in the FIG. 1B is first to remove the oxide formed on the surface of the silicon wafer 100. Next, a solution containing KOH is applied to the silicon wafer 100 to perform an anisotropic etching process. Since the solution has a higher etching rate on the <100> face rather than the <111> face of the silicon wafer 100, a groove with a pyramid shape is formed after the etching process. Since no pattern is formed in the surface of the silicon wafer 100, various grooves with different scales are formed. It is noted that, in other embodiments, TMAH or EDP also may be used as the etching solution. After the master mold 104 is finished, a modeling process is performed so as to form a mold 102 with the pattern of the master mold 104. For performing a electroform process, a conductive layer is first formed in the master mold 104 by sputtering or evaporation method. It is noted that any kind of conductive material can be used to form the conductive layer. After the conductive layer is finished, the master mold 104 is placed into an electrobath to perform a well-known electroform process to form the mold 102 as shown in the FIG. 1C. After the mold 102 is finished, a well-known manufacturing method, such as compression or injection molding, can be used to mass produce the prism.

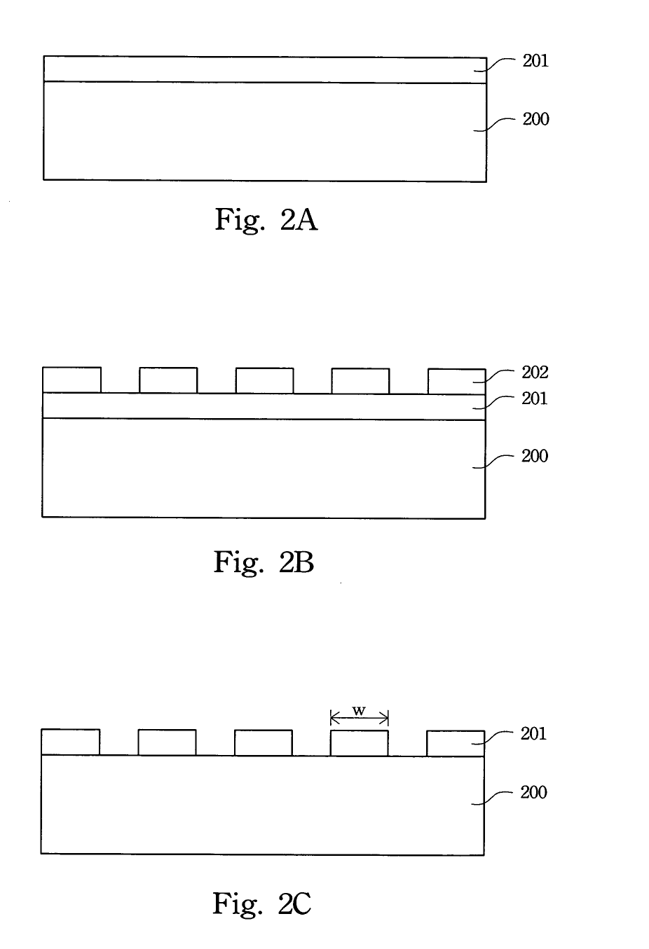

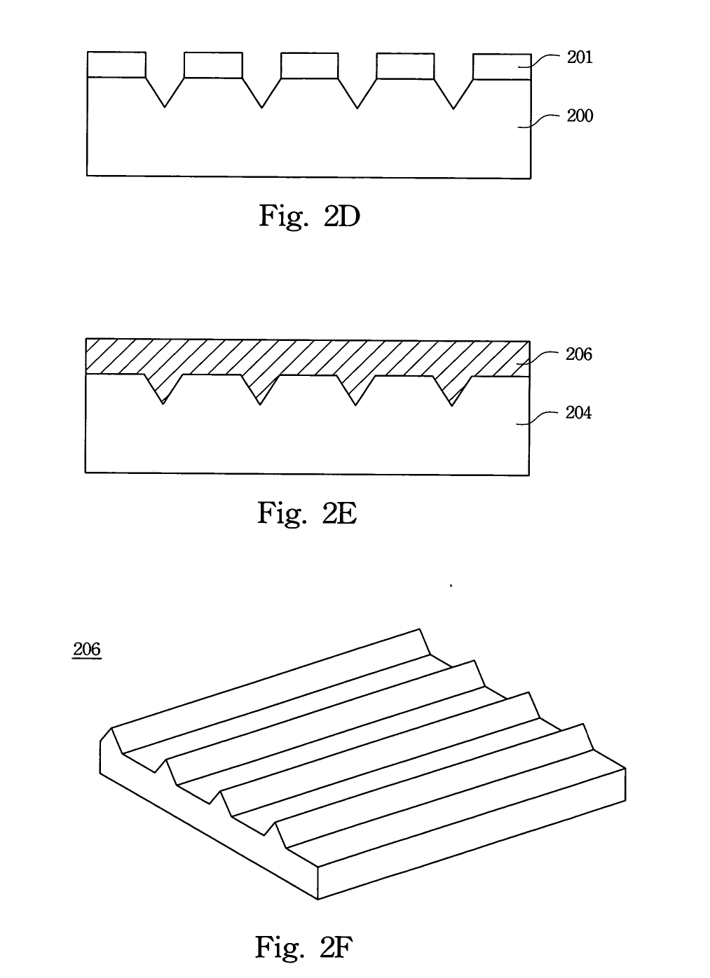

FIG. 2A to FIG. 2E illustrate the second embodiment, which forms a mold with strip structure. First, as shown in FIG. 2A, a silicon wafer 200 is provided. The silicon wafer 200 may be an N⁺-type or P⁺-type silicon wafer. According to the preferred embodiment, a silicon wafer with a Miller index <100> is used in the present invention. Next, an oxidation process, or other well-known process, is performed to form a oxide layer over the silicon wafer 200. According to the preferred embodiment, this oxide layer is a silicon dioxide layer 201.

Next, as shown in the FIG. 2B, a photoresist layer is formed over the silicon dioxide layer 201. A photolithography process is then performed to form a patterned photoresist layer 202.

Then, as shown in the FIG. 2C, an etching process is performed in the silicon dioxide layer 201 using the patterned photoresist layer 202 as a mask. A dry or wet etching process can be applied in the present invention. According to the preferred embodiment, a wet etching process using Ammonium Fluoride and Hydrofluoric Acid solution is used in the present invention to transfer the pattern of the photoresist layer 202 to the silicon dioxide layer 201. After the etching process is finished, a well-known method is used to remove the photoresist layer 202. FIG. 2C illustrates a cross-sectional view of the silicon wafer after removing the photoresist layer 202.

Next, as shown in FIG. 2D, a wet etching process is performed to etch the wafer 200, where the silicon dioxide layer 201 is used as a mask during the etching process. According to the preferred embodiment, a solution containing KOH is applied to the silicon wafer 200 to perform an anisotropic etching process so as to form a “V”-type groove. It is noted that, in other embodiments, the TMAH or EDP also may be used as the etching solution. Finally, the silicon dioxide layer 201 is removed to form the master mold 204 as shown in FIG. 2E.

After the master mold 204 is finished, an electroform process is performed to form a mold 206. First, a conductive layer is formed in the master mold 204 by sputtering or evaporation. After the conductive layer is finished, the master mold 204 is placed into an electrobath to perform a well-known electroform process so as to form the mold 206 as shown in FIG. 2F. After the mold 206 is finished, a well-known manufacturing method, such as compression or injection molding, can be used to mass produce the prism. It is noted that the scale of the prism structure is related to the scale W of the silicon dioxide layer 201 as shown in the FIG. 2C. In other words, the scale of the prism structure can be changed by using a photolithography process to change the scale W of the silicon dioxide layer 201.

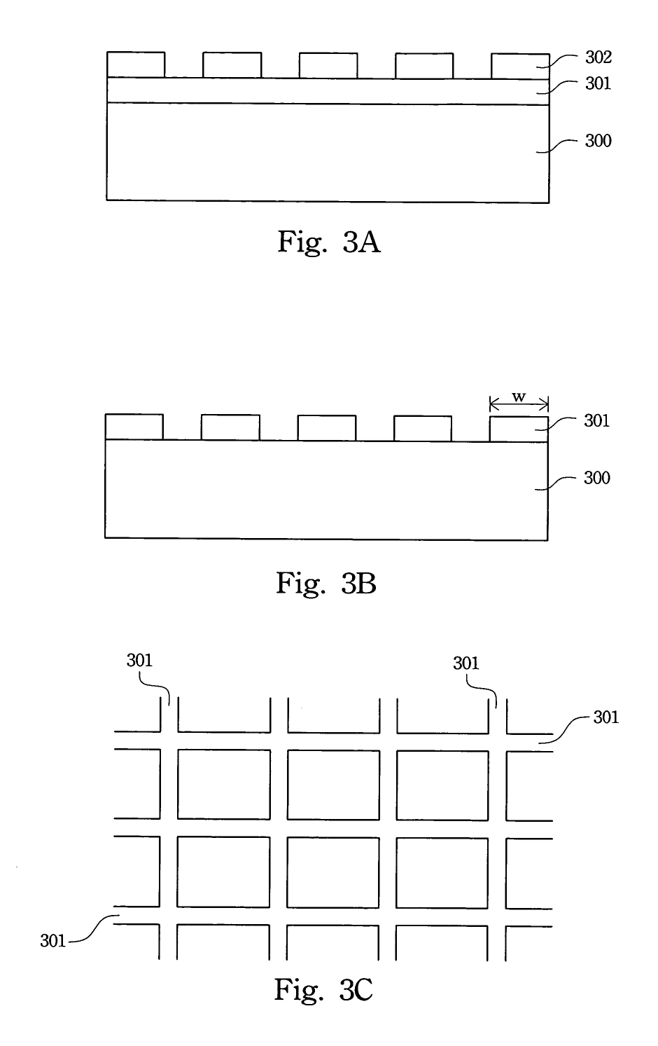

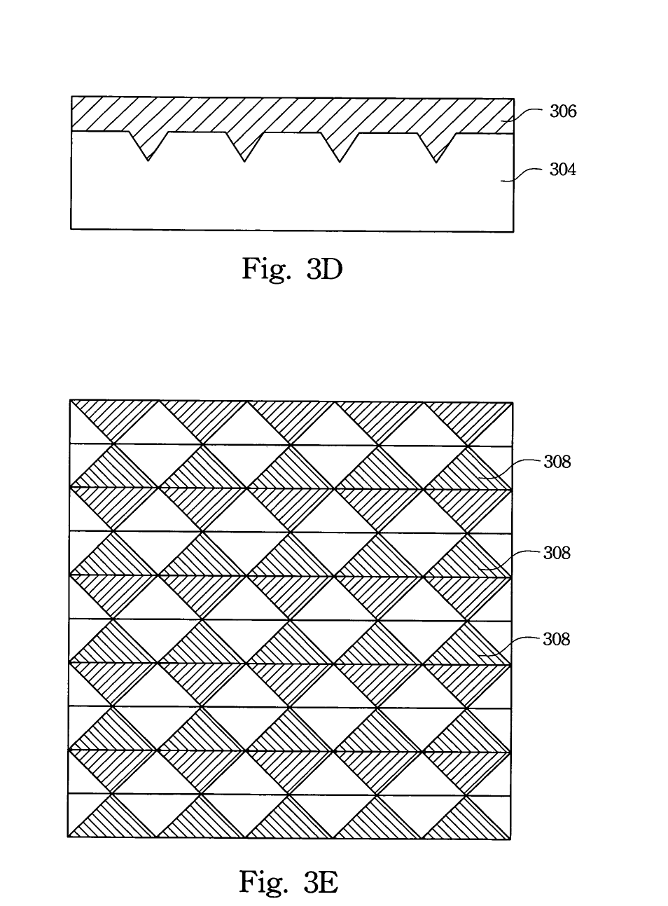

FIG. 3A to FIG. 3E illustrate the third embodiment, which forms a mold with a same-scale pyramid structure. First, as shown in FIG. 3A, a silicon wafer 300 is provided. The silicon wafer 300 may be an N⁺-type or P⁺-type silicon wafer. According to the preferred embodiment, a silicon wafer with a Miller index <100> is used in the present invention. Next, an oxidation process, or other well-known process, is performed to form a oxide layer over the silicon wafer 300. According to the preferred embodiment, this oxide layer is a silicon dioxide layer 301. Next, a photoresist layer is formed over the silicon dioxide layer 301. A photolithography process is performed to form a patterned photoresist layer 302.

Then, as shown in FIG. 3B, an etching process is performed in the silicon dioxide layer 301 using the patterned photoresist layer 302 as a mask. A dry etching process or a wet etching process can be used in the present invention. According to the preferred embodiment, a wet etching process using Ammonium Fluoride and Hydrofluoric Acid solution is used in the present invention to transfer the pattern of the photoresist layer 302 to the silicon dioxide layer 301. After the etching process is finished, a well-known method is used to remove the photoresist layer 302. The purpose of this embodiment is to form a mold with a same-scale pyramid structure. Therefore, the pattern of the silicon dioxide layer 301 is a grid structure. FIG. 3C illustrates the top view of FIG. 3B.

Next, as shown in FIG. 3D, a wet etching process is performed to etch the wafer 300, where the silicon dioxide layer 301 is used as a mask during etching process. According to the preferred embodiment, a solution containing KOH is applied to the silicon wafer 300 to perform an anisotropic etching process so as to form groove with pyramid structure. It is noted that, in other embodiments, TMAH or EDP also may be used as the etching solution. Finally, the silicon dioxide layer 301 is removed to form the master mold 304. After the master mold 304 is finished, a conductive layer is formed in the master mold 304 by sputtering or evaporation. Then, the master mold 304 is placed into an electrobath to perform a well-known electroform process so as to form the mold 306.

FIG. 3E is a top view of the mold 306. Since the pattern of the silicon dioxide layer 301 is a grid structure, the grooves with same-scale pyramid structure are formed over the wafer 300. Therefore, a same-scale pyramid structure 308 is also formed in the surface of the mold 306. Then, a well-known manufacturing method, such as compression or injection moldng, can be used to mass produce the prism. It is noted that the scale of the prism structure is related to the width W of the silicon dioxide layer 301 as shown in FIG. 3B and FIG. 3C. In other words, the scale of the prism structure can be changed by using a photolithography process to change the width W of the silicon dioxide layer 301.

It is noted that the foregoing examples are only the part of various embodiments. The different semiconductor process may be used in the present invention to form different mold, and so that to form different prism structure.

Accordingly, the present invention provides a prism manufacturing method. According to the method, a semiconductor process method is applied on a wafer for forming a master mold. Then, an electroform process is applied to the master mold for forming a mold. Then, the mold can be used to mass-produce prisms by a well-known manufacturing method, such as compression or injection molding. Since no machining process is involved in the present invention, the mold scale is related to the semiconductor process technology. In other words, when the semiconductor process technology reachs the nanometer scale, a nanometer scale mold and a prism may be generated.

As is understood by a person skilled in the art, the foregoing descriptions of the preferred embodiment of the present invention are an illustration of the present invention rather than a limitation thereof. Various modifications and similar arrangements are included within the spirit and scope of the appended claims. The scope of the claims should be accorded to the broadest interpretation so as to encompass all such modifications and similar structures. While a preferred embodiment of the invention has been illustrated and described, it will be appreciated that various changes can be made therein without departing from the spirit and scope of the invention.

What is claimed is:

1. A prism manufacturing method, comprising:
using a semiconductor process method to form a master mold structure over a wafer;
applying an electroform process in said master mold to form a mold with a structure corresponding to a structure of the master mold; and
using said mold to fabricate prisms.

2. The method of claim 1, wherein said mold is used in a compression molding process or an injection molding process to fabricate prisms.

3. The method of claim 1, wherein before applying an electroform process in making said mold, a metal layer is formed over said master mold.

4. The method of claim 3, wherein a sputtering method or an evaporation method is used to form a metal layer over said master mold.

5. The method of claim 1, wherein said wafer has a Miller index <100>.

6. The method of claim 1, wherein said semiconductor process method comprises a wet etching process.

7. The method of claim 6, wherein a KOH solution, an EDP solution or a TMAH solution is used in said wet etching process.

8. The method of claim 1, wherein said semiconductor process method comprises patterning said wafer and then applying a wet etching process in said patterned wafer.

9. The method of claim 8, wherein patterning said wafer further comprises forming an oxide layer over said wafer and then patterning said oxide layer.

10. The method of claim 11, wherein said oxide layer is a silicon dioxide layer.

11. The method of claim 8, wherein a KOH solution, an EDP solution or a TMAH solution is used in said wet etching process.

12. A prism manufacturing method, comprising:
using a semiconductor process method to form a master mold structure over a wafer, wherein the semiconductor process method comprises etching said wafer;
forming a conductive layer over said master mold;
applying an electroform process to said master mold to form a mold with a structure corresponding to a structure of the master mold; and
using said mold to fabricate prisms.

13. The method of claim 12, wherein said mold is used in a compression molding process or an injection molding process to fabricate prisms.

14. The method of claim 12, wherein a sputtering method or an evaporation method is used to form a metal layer over said master mold.

15. The method of claim 12, wherein said wafer has a Miller index <100>.

16. The method of claim 12, wherein a wet etching process is used to etch said wafer.

17. The method of claim 16, wherein said wet etching process uses a KOH solution, an EDP solution or a TMAH solution.

18. The method of claim 12, wherein said semiconductor process further comprises patterning said wafer.

19. The method of claim 18, wherein patterning said wafer further comprises forming an oxide layer over said wafer and then patterning said oxide layer.

20. The method of claim 19, wherein said oxide layer is a silicon dioxide layer.
